(19) United States
(12) Patent Application Publication
(10) Pub. No.: US 2016/0224520 A1
(43) Pub. Date: Aug. 4, 2016

(54) ENCODING METHOD AND ENCODING DEVICE

(71) Applicant: FUJITSU LIMITED, Kawasaki-shi (JP)

(72) Inventors: Masahiro KATAOKA, Kamakura (JP); Ryo MATSUMURA, Numazu (JP); Takafumi OHTA, Tokyo (JP)

(73) Assignee: FUJITSU LIMITED, Kawasaki-shi (JP)

(21) Appl. No.: 15/010,056

(22) Filed: Jan. 29, 2016

(30) Foreign Application Priority Data
Jan. 30, 2015 (JP) 2015-017618

(51) Int. Cl. G06F 17/22; H03M 7/30; G06F 17/27

(52) U.S. Cl. CPC G06F 17/2276; G06F 17/2735; G06F 17/278; H03M 7/3088

(57) ABSTRACT

An encoding unit encodes first encoding each of first words in a target file utilizing a first code allocation rule, each of the first words having an appearance frequency larger than an appearance frequency of a word positioned at a given ordinal rank in word frequency information, the word frequency information being information of word frequencies in a plurality of files that the target file is included, the first code allocation rule being generated from the word frequency information, and the encoding unit encodes at least a second word in the target file into a code with a first code length utilizing a second code allocation rule, the second word having appearance frequency smaller than the appearance frequency of the word positioned at the given ordinal rank in the word frequency information, the second code allocation rule being different from the first code allocation rule.

### CROSS-REFERENCE TO RELATED APPLICATIONS

This application is based upon and claims the benefit of priority of the prior Japanese Patent Application No. 2015-017618, filed on Jan. 30, 2015, the entire contents of which are incorporated herein by reference.

### FIELD

The embodiment discussed herein is directed to a computer-readable recording medium, an encoding method, and an encoding device.

### BACKGROUND

A technology has been used that compresses a target text for compression, word by word, by using a static dictionary. The static dictionary is a dictionary in which each word is associated with a compressed code. With the technology, the appearance frequency of each word extracted from a plurality of texts is obtained. The compressed code of the code length corresponding to the appearance frequency is associated with each word and registered on the static dictionary. In the static dictionary, shorter code lengths are allocated to the words having higher appearance frequencies and longer code lengths are allocated to the words having lower appearance frequencies. Conventional technologies are described in Japanese Laid-open Patent Publication No. 62-017872, Japanese Laid-open Patent Publication No. 11-215007, and Japanese Laid-open Patent Publication No. 2000-269822, for example.

Unfortunately, allocating the code length based on the appearance frequency in the population lengthens the code length allocated to the word having a low appearance frequency, leading to a decreased compression rate.

### SUMMARY

According to an aspect of an embodiment, a non-transitory computer-readable recording medium stores a program that causes a computer to execute a process. the process includes, first encoding each of first words in a target file utilizing a first code allocation rule, each of the first words having an appearance frequency larger than an appearance frequency of a word positioned at a given ordinal rank in word frequency information, the word frequency information being information of word frequencies in a plurality of files that the target file is included, the first code allocation rule being generated from the word frequency information, and second encoding at least a second word in the target file into a code with a first code length utilizing a second code allocation rule, the second word having appearance frequency smaller than the appearance frequency of the word positioned at the given ordinal rank in the word frequency information, the second code allocation rule being different from the first code allocation rule.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram for explaining a dictionary according to a first reference example;

FIG. 2 is a diagram for explaining compression according to the first reference example;

FIG. 3 is a first diagram for explaining a dictionary according to a first embodiment of the present invention;

FIG. 4 is a diagram for explaining compression according to the first embodiment;

FIG. 5 is a diagram for explaining the relation between processors and a storage unit in an information processing apparatus according to the first embodiment;

FIG. 6 is a diagram illustrating an example of the system configuration of a compression process according to the first embodiment;

FIG. 7 is a first diagram for explaining generation of a compression dictionary according to the first embodiment;

FIG. 8 is a second diagram for explaining the generation of the compression dictionary according to the first embodiment;

FIG. 9 is a third diagram for explaining the generation of the compression dictionary according to the first embodiment;

FIG. 10 is a diagram for explaining a character-and-symbol portion of the compression dictionary according to the first embodiment;

FIG. 11 is a second diagram for explaining the compression according to the first embodiment;

FIG. 12 is a flowchart for explaining the entire flow of the compression process according to the first embodiment;

FIG. 13 is a flowchart illustrating an example of the flow of a sampling process according to the first embodiment;

FIG. 14 is a flowchart illustrating an example of the flow of a one-pass compression process according to the first embodiment;

FIG. 15 is a diagram illustrating an example of the system configuration of an expansion process according to the first embodiment;

FIG. 16 is a diagram for explaining an expansion dictionary according to the first embodiment;

FIG. 17 is a diagram for explaining expansion according to the first embodiment;

FIG. 18 is a flowchart illustrating an example of the flow of expanding a compressed code according to the first embodiment;

FIG. 19 is a diagram for explaining extension of a low-frequency word area according to the first embodiment;

FIG. 20 is a diagram illustrating the hardware configuration of the information processing apparatus according to the first embodiment;

FIG. 21 is a diagram illustrating a configuration example of computer programs running on a computer according to the first embodiment; and

FIG. 22 is a diagram illustrating a configuration example of devices in a system according to the first embodiment.

### DESCRIPTION OF EMBODIMENTS

Preferred embodiments of the present invention will be explained with reference to accompanying drawings. The embodiments are not intended to limit the scope of the present invention. The embodiments may be combined as appropriate to the extent to which the processes are consistent with each other.

### [a] First Embodiment

### Dictionary According to First Reference Example

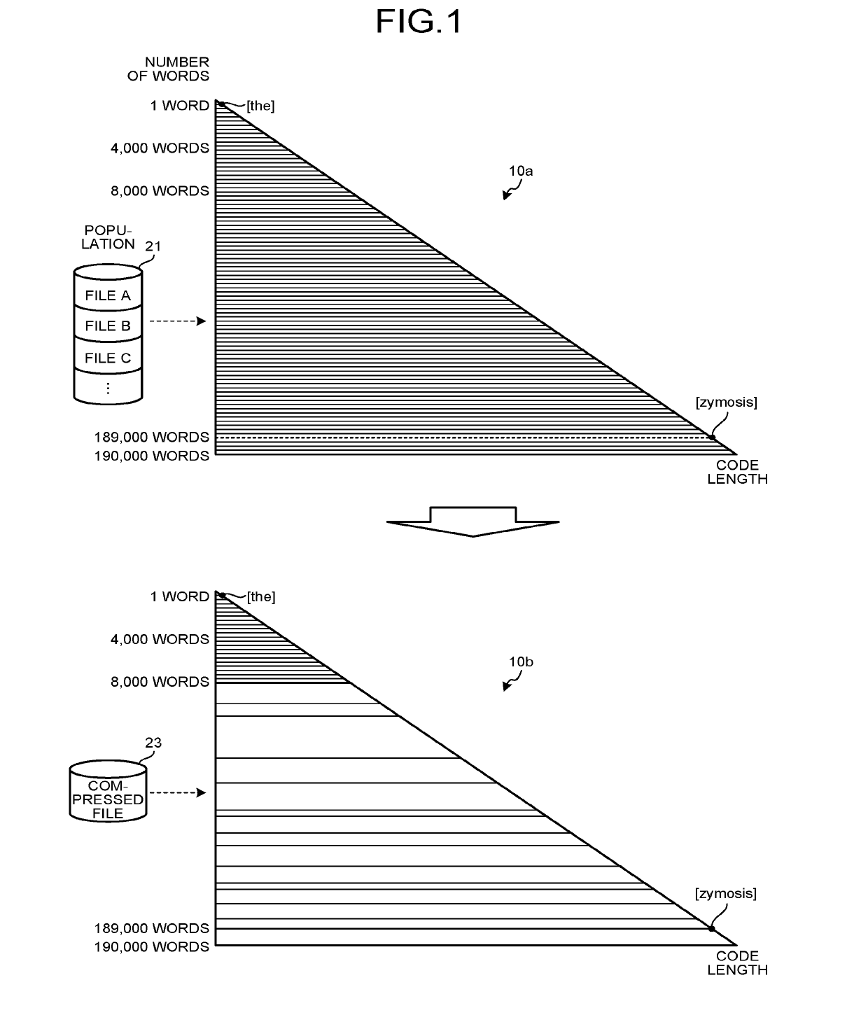

The following describes a dictionary according to a first reference example with reference to FIG. 1. FIG. 1 is a diagram for explaining the dictionary according to the first reference example. The dictionary according to the first reference example includes words collected from files including a file A, a file B, and a file C in a population 21. For example, the dictionary includes about 190,000 words collected from various documents and popular dictionaries and registered as the population 21. FIG. 1 illustrates a distribution chart 10a illustrating the distribution of the words registered on the dictionary. The population refers to a plurality of text files used for collecting words to be registered on the dictionary. The vertical axis of the distribution chart 10a represents the number of words. In the distribution chart 10a, the smaller number of words indicates a higher appearance frequency in the population 21, and the larger number of words indicates a lower appearance frequency. That is, the number of words represents the appearance order of the words in the population. For example, the word “the” having a relatively high appearance frequency in the population 21 is positioned at the number of words “10 words”, and the word “zymosis” having a relatively low appearance frequency is positioned at the number of words “189,000 words”. The word having the lowest appearance frequency in the population 21 is positioned at “190,000 words”.

The horizontal axis of the distribution chart 10a represents a code length. The code length corresponding to the appearance frequency in the population 21 is allocated to each of the words included in the dictionary according to the first reference example. Shorter code lengths are allocated to the words having higher appearance frequencies in the population 21, and longer code lengths are allocated to the words having lower appearance frequencies. For example, the word “zymosis” has a lower appearance frequency than the word “the” in the population 21, and as illustrated in the distribution chart 10a, a longer code length is allocated to the word “zymosis” having a lower appearance frequency. Hereinafter, the words positioned from rank 1 to 8,000 in the ordinal rank of the appearance frequency in the population are called high-frequency words, and the words positioned at rank 8,001 or below in the ordinal rank of the appearance frequency are called low-frequency words. The appearance order rank 8,000 serving as a borderline between the high-frequency words and the low-frequency words is described as merely an example. Other appearance order rank may serve as the borderline.

The horizontal stripes in the distribution chart 10a represent the positions of the number of words corresponding to the words that appear in the population 21. The portion of the horizontal stripes with a high density represents that a large number of words appear and thus the distribution density is high. The portion of the horizontal stripes with a low density represents that a small number of words appear and thus the distribution density is low. All of the 190,000 words collected from the population are stored in the dictionary according to the first reference example. Accordingly, the distribution chart 10a illustrates the horizontal stripes with a high density uniformly extending through the area from the number of words 1 to 190,000, that is, from the high-frequency words to the low-frequency words.

As described above, as illustrated in the distribution chart 10a, the code lengths are allocated to the high-frequency words and the low-frequency words in accordance with the appearance frequency of the words in the population. However, as illustrated in the distribution chart 10a, code lengths allocated to low-frequency words can be long. For example, the word “zymosis” is a low-frequency word and positioned at rank 189,000 in the appearance order, at a lower position out of the low-frequency words. Accordingly, the code length allocated thereto is long.

A compressed file 23 is a file obtained by encoding a target file to be compressed. The compressed file 23 includes about 32,000 words out of the 190,000 words registered on the dictionary. FIG. 1 also illustrates a distribution chart 10b illustrating the distribution of the words registered on the compressed file 23 out of the words registered on the dictionary. The vertical axis of the distribution chart 10b represents the number of words and the horizontal axis represents the code length, in the same manner as the distribution chart 10a. Most of the high-frequency words positioned from rank 1 to 8,000 of the number of words appear in the compressed file 23. Accordingly, in the distribution chart 10b, the horizontal stripes with a high density uniformly extend through the area from the number of words 1 to 8,000, that is, in an area of the high-frequency words. By contrast, few of the low-frequency words positioned from rank 8,001 to 190,000 of the number of words appear in the compressed file 23. Accordingly, in the distribution chart 10b, the horizontal stripes with a low density uniformly extend through the area from the number of words 8,001 to 190,000, that is, in an area of the low-frequency words.

The code length corresponding to the appearance frequency of each word in the population 21 is allocated to each of the words included in the compressed file 23, for example. In this case, in the compressed file 23, the low-frequency words have various code lengths and longer code lengths are allocated to low-frequency words with a smaller number of words. For example, long code lengths are allocated to low-frequency words positioned at or near the bottom of the distribution chart 20b, such as the word “zymosis”. Accordingly, when the compressed file 23 is compressed by using a compressed code of the code length allocated to the compression of each word, variable-length codes allocated to the low-frequency words positioned at low appearance order are redundant, which reduces the compression rate of the compressed file 23.

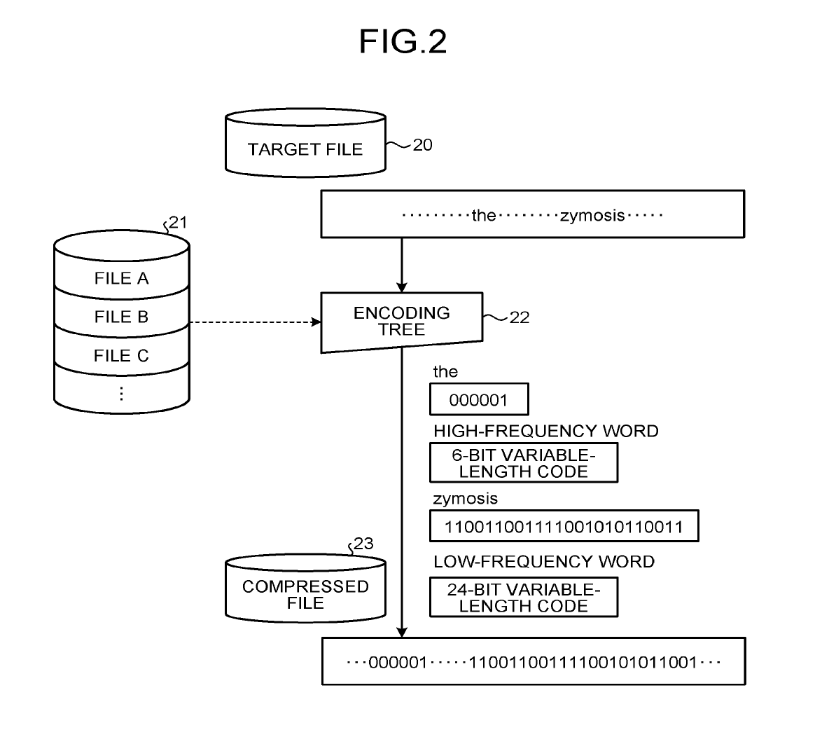

The following describes more specifically the flow of the compression according to the first reference example. FIG. 2 is a diagram for explaining the compression according to the first reference example. An encoding tree 22 is a dictionary generated by allocating a compressed code to each of the about 190,000 words extracted from the population 21. The population 21 includes a plurality of text files including the file A, the file B, and the file C. The words such as “the” and “zymosis” are extracted from the population 21. A variable-length code of the code length corresponding to the appearance frequency in the population is allocated to each of the extracted words. The variable-length code refers to a compressed code having a variable code length. For example, a 6-bit variable-length code is allocated to one of the high-frequency words “the”. For another example, a 24-bit variable-length code is allocated to one of the low-frequency words “zymosis”. The variable-length code allocated to each word is registered on the encoding tree 22. In this manner, the encoding tree 22 is generated.

The compressed file 23 is generated by allocating a variable-length code registered on the encoding tree 22 to each of the words extracted from a target file 20. The target file is a file to be compressed. For example, the words such as “the” and “zymosis” are extracted from the target file 20. A 6-bit variable-length code “000001” registered on the encoding tree 22 is allocated to the high-frequency word “the” extracted from the target file 20 and output to the compressed file 23. A 24-bit variable-length code “110011001111001010110011” registered on the encoding tree 22 is allocated to the low-frequency word “zymosis” extracted from the target file 20 and output to the compressed file 23.

As a result, variable-length codes allocated to the low-frequency words positioned at low appearance order are redundant, which reduces the compression rate of the compressed file 23 generated from the target file 20.

### Dictionary According to First Embodiment

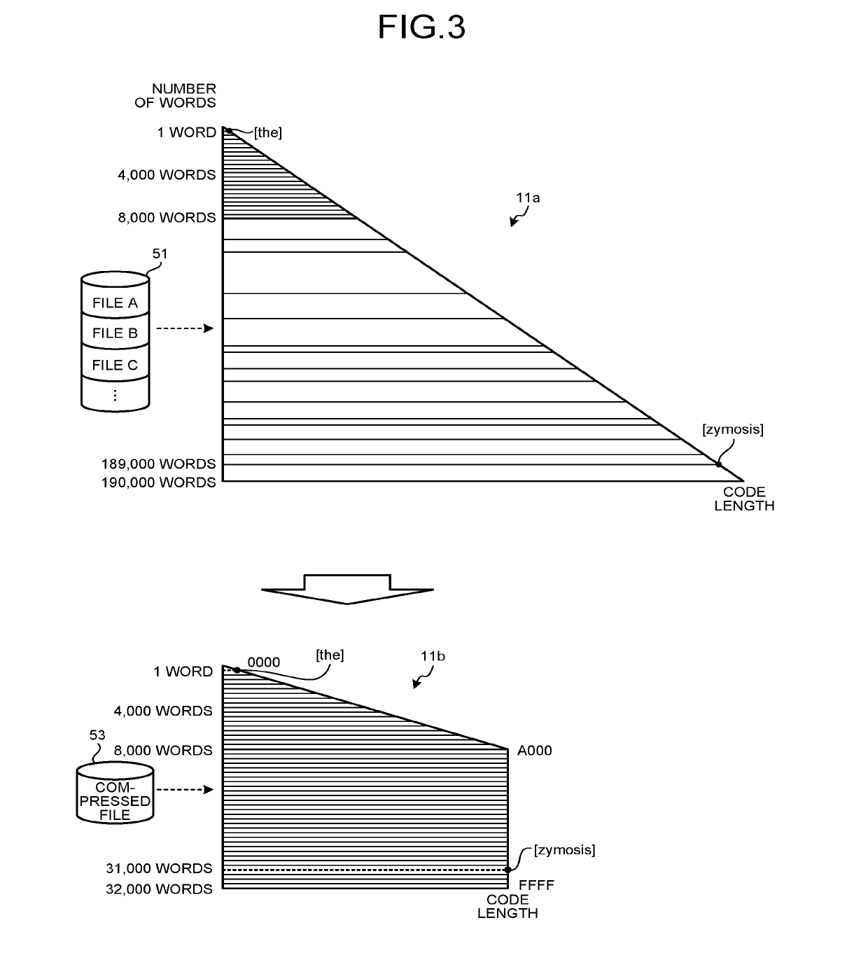

The following describes a dictionary according to a first embodiment with reference to FIG. 3. FIG. 3 is a first diagram for explaining the dictionary according to the first embodiment. In distribution charts 11a and 11b illustrated in FIG. 3, the vertical axis represents the number of words and the horizontal axis represents the code length, in the same manner as those in FIG. 1.

An information processing apparatus 100 according to the first embodiment generates a dictionary based on a population 51 including a file A, a file B, and a file C. The population 51 may include a file to be encoded. About 190,000 words are registered on this generated dictionary and a compressed file 53 includes about 32,000 words out of the 190,000 words registered on the dictionary. The distribution chart 11a illustrates the distribution of 32,000 words included in the compressed file 53 in common out of the 190,000 words registered on the dictionary. The distribution chart 11a is the same as the distribution chart 10b according to the first reference example in FIG. 1.

The horizontal stripes in the distribution chart 11a represent the positions of the number of words corresponding to the words that appear in the compressed file 53. The portion of the horizontal stripes with a high density represents that a large number of words appear and thus the distribution density is high. The portion of the horizontal stripes with a low density represents that a small number of words appear and thus the distribution density is low. As illustrated in the distribution chart 11a, in the area of the number of words 1 to 8,000, the horizontal stripes have a high density and the distribution density of the words that appear is high. By contrast, in the area of the number of words 8,001 to 190,000, the horizontal stripes have a low density and the distribution density of the words that appear is low.

For example, the high-frequency words such as “the”, “a”, and “of” positioned from rank 1 to 8,000 in the appearance order in the dictionary are mostly included in the compressed file 53 in common. Accordingly, in the distribution chart 11a, the area of the number of words 1 to 8,000 has a high distribution density of the words. By contrast, the low-frequency words such as “zymosis” positioned at 8,001 or below in the appearance order in the dictionary are seldom included in the compressed file 53 in common. Accordingly, the area of the number of words 8,001 to 190,000 has a low distribution density of the words that appear.

The information processing apparatus 100 allocates variable-length codes to all of the high-frequency words. The information processing apparatus 100 allocates fixed-length codes to the low-frequency words included in the compressed file 53. The information processing apparatus 100 then registers the variable-length codes and the fixed-length codes allocated to the words on the dictionary. The information processing apparatus 100 does not necessarily allocate compressed codes to low-frequency words included in the dictionary but not included in the compressed file 53.

For example, as illustrated in 11b in FIG. 3, the information processing apparatus 100 allocates 1- to 16-bit variable-length codes to the high-frequency words positioned from rank 1 to 8,000 in the appearance order out of the words included in the compressed file. The information processing apparatus 100 allocates 16-bit fixed-length codes to the low-frequency words positioned from rank 8,001 to 32,000 in the appearance order. Specifically, the information processing apparatus 100 allocates the variable-length codes from “0000h” to “9FFFh” to all of the high-frequency words and allocates the fixed-length codes from “A000h” to “FFFFh” to the low-frequency words included in the compressed file 53. The distribution chart 11b illustrates the distribution of the words included in the compressed file 53 in the dictionary. As illustrated in the distribution chart 11b, it is understood that the horizontal stripes have a high density as a whole and the distribution density of the words is high as a whole.

The information processing apparatus 100 generates the compressed file 53 by using the dictionary in which the variable-length codes are allocated to the high-frequency words, and the fixed-length codes are allocated to the low-frequency words, as illustrated in the distribution chart 11b. This operation enables the information processing apparatus 100 to reduce the code length of the low-frequency words included in the compressed file 53. For example, the code length of the word “zymosis” illustrated in the distribution chart 11b in FIG. 3 is smaller than that of the word “zymosis” illustrated in the distribution chart 11a. As described above, the information processing apparatus 100 can achieve reduction in the code length of the compressed code allocated to the low-frequency words by using the dictionary according to the first embodiment in comparison with using the dictionary according to the first reference example.

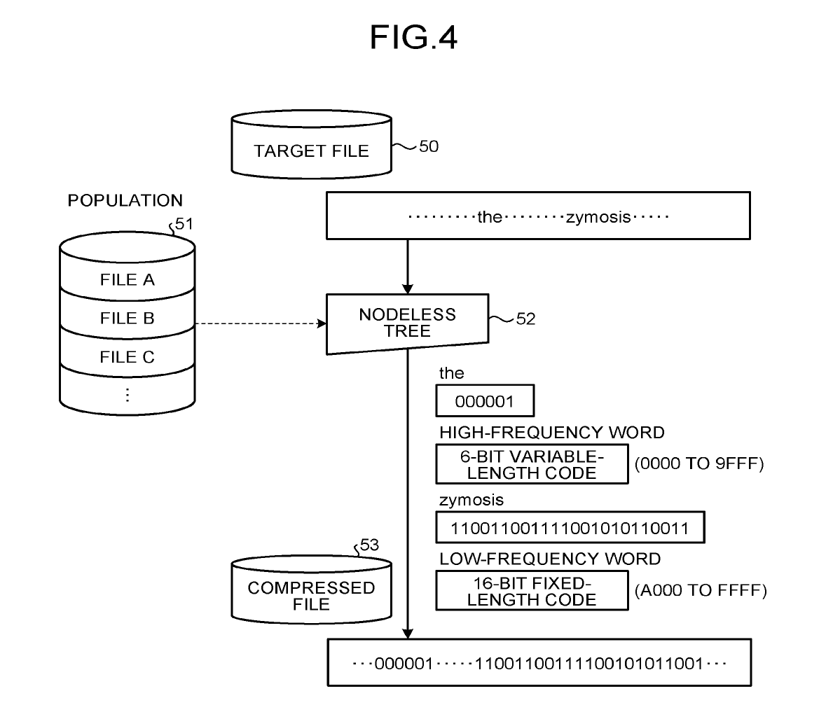

The following describes a compression process in which the information processing apparatus 100 according to the first embodiment encodes the words included in the target file 50 for compression with reference to FIG. 4. FIG. 4 is a diagram for explaining the compression according to the first embodiment. Firstly, the information processing apparatus 100 registers the words included in the population 51 on a nodeless tree 52. For example, the information processing apparatus 100 registers about 190,000 words registered on various documents and popular dictionaries, on the nodeless tree 52. The nodeless tree 52 is the dictionary according to the first embodiment. The population 51 may include the target file 50. The information processing apparatus 100 allocates a variable-length code or a fixed-length code to the words included in the target file 50 such as the words “the” and “zymosis” out of the words registered on the nodeless tree 52.

The information processing apparatus 100 tallies the appearance frequency in the target file 50 of each word extracted from the population 51. The information processing apparatus 100 allocates 1- to 16-bit variable-length codes to the high-frequency words positioned from rank 1 to 8,000 in the appearance order in the target file 50 of each word extracted from the population 51, and registers the variable-length codes on the nodeless tree 52. For example, the information processing apparatus 100 allocates a 6-bit variable-length code “000001” to the high-frequency word “the”, and registers the variable-length code “000001” on the nodeless tree 52.

Subsequently, the information processing apparatus 100 compresses the target file 50 based on the nodeless tree 52, and executes a process for generating the compressed file 53. Firstly, the information processing apparatus 100 reads the target file 50 and extracts the high-frequency word “the” from the target file 50. The information processing apparatus 100 allocates a 6-bit variable-length code “000001” registered on the nodeless tree 52 to the extracted word “the” and outputs the variable-length code “000001” to the compressed file 53.

The information processing apparatus 100 then reads the target file 50 and extracts the low-frequency word “zymosis” from the target file 50. The information processing apparatus 100 allocates a 16-bit fixed-length code “1010010011010010” to the low-frequency word “zymosis” and registers the fixed-length code “1010010011010010” associated with the low-frequency word “zymosis” on the nodeless tree 52. The information processing apparatus 100 outputs the fixed-length code “1010010011010010” registered on the nodeless tree 52 to the compressed file 53. If the information processing apparatus 100 extracts the low-frequency word “zymosis” from the target file 50 next, the information processing apparatus 100 acquires the fixed-length code “1010010011010010” from the nodeless tree 52 because the word “zymosis” has been already registered on the nodeless tree 52, and outputs the acquired fixed-length code to the compressed file 53.

As described above, the information processing apparatus 100 allocates the fixed-length codes to the low-frequency words extracted from the target file 50, registers the fixed-length codes allocated to the low-frequency words on the nodeless tree 52, and outputs the fixed-length codes registered on the nodeless tree 52 to the compressed file 53, thereby compressing a file through one pass.

### Configuration of Processors Related to Compression Process According to First Embodiment

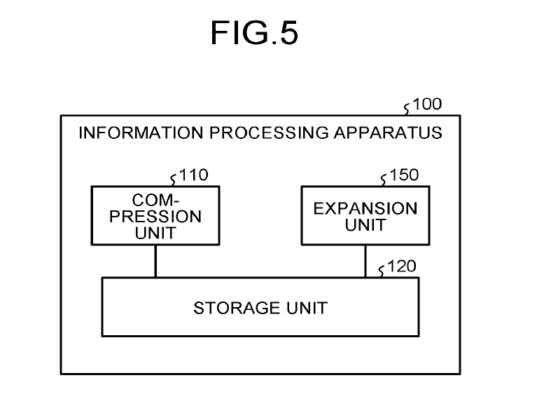

The following describes the relation between processors and a storage unit in the information processing apparatus 100 with reference to FIG. 5. The information processing apparatus 100 is an example of an encoding device. FIG. 5 is a diagram for explaining the relation between the processors and the storage unit in the information processing apparatus. As illustrated in FIG. 5, a storage unit 120 in the information processing apparatus 100 is coupled to a compression unit 110 and an expansion unit 150. The compression unit 110 compresses target files. The expansion unit 150 expands compressed files. Examples of the storage unit 120 include semiconductor memories such as a random access memory (RAM), a read only memory (ROM), and a flash memory, or storage devices such as a hard disk drive and an optical disc drive.

The information processing apparatus 100 includes the compression unit 110 and the expansion unit 150. The functions of the compression unit 110 and the expansion unit 150 can be implemented by a central processing unit (CPU) executing a certain computer program, for example. The functions of the compression unit 110 and the expansion unit 150 can be implemented by integrated circuits such as an application specific integrated circuit (ASIC) and a field programmable gate array (FPGA).

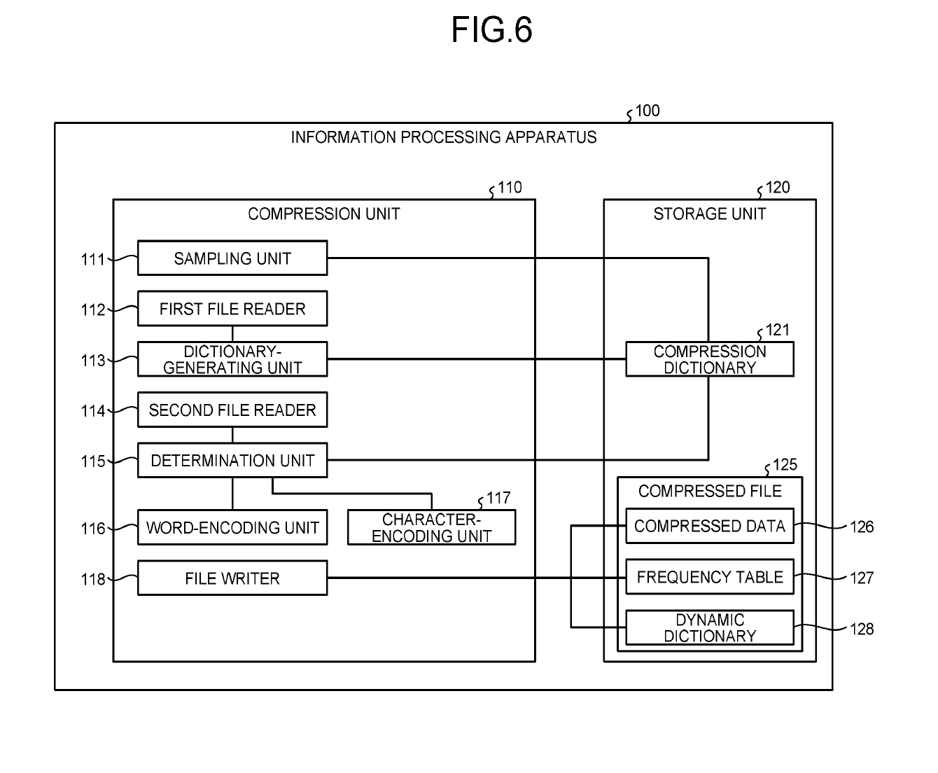

The following describes the compression process according to the first embodiment with reference to FIG. 6. FIG. 6 is a diagram illustrating an example of the system configuration of the compression process according to the first embodiment. As illustrated in FIG. 6, the information processing apparatus 100 includes the compression unit 110 and the storage unit 120. The compression unit 110 includes a sampling unit 111, a first file reader 112, a dictionary-generating unit 113, a second file reader 114, a determination unit 115, a word-encoding unit 116, a character-encoding unit 117, and a file writer 118. The storage unit 120 includes a compression dictionary 121 and a compressed file 125. The compressed file 125 includes compressed data 126, a frequency table 127, and a dynamic dictionary 128.

The compression unit 110 allocates a variable-length compressed code having a length equal to or smaller than a given length to each of the words positioned at a given ordinal rank or above of the appearance frequency in the target file. The compression unit 110 allocates a compressed code of a given length to each of the words positioned below a given ordinal rank of the appearance frequency. The compression unit 110 compresses the target file by using the compressed codes allocated to the words. For example, the compression unit 110 acquires a plurality of words from a population including one or more files. The compression unit 110 allocates a compressed code to each of the words included in the target file out of the words acquired from the population. The following describes in detail processors in the compression unit 110.

Processors in Compression Unit 110

The compression unit 110 includes the sampling unit 111, the first file reader 112, the dictionary-generating unit 113, the second file reader 114, the determination unit 115, the word-encoding unit 116, the character-encoding unit 117, and the file writer 118. The following describes processors in the compression unit 110.

The sampling unit 111 is a processor that registers the words collected from the population on a compression dictionary 121a. The sampling unit 111 collects about 190,000 words from the text files included in the population, and registers the words as basic words. The sampling unit 111 sorts the registered basic words so as to be stored in the alphabetical order in the compression dictionary 121a. The sampling unit 111 associates the basic word with a 2-gram and a bitmap by using a pointer-to-basic-word in the compression dictionary 121a.

The sampling unit 111 allocates a 3-byte static code to each of the registered basic words. The static code is a 3-byte word code to be uniquely allocated to each of the words collected from the population. For example, the sampling unit 111 allocates a static code “A0007Bh” to a basic word “able”. The sampling unit 111 also allocates a static code “A00091h” to another basic word “about”.

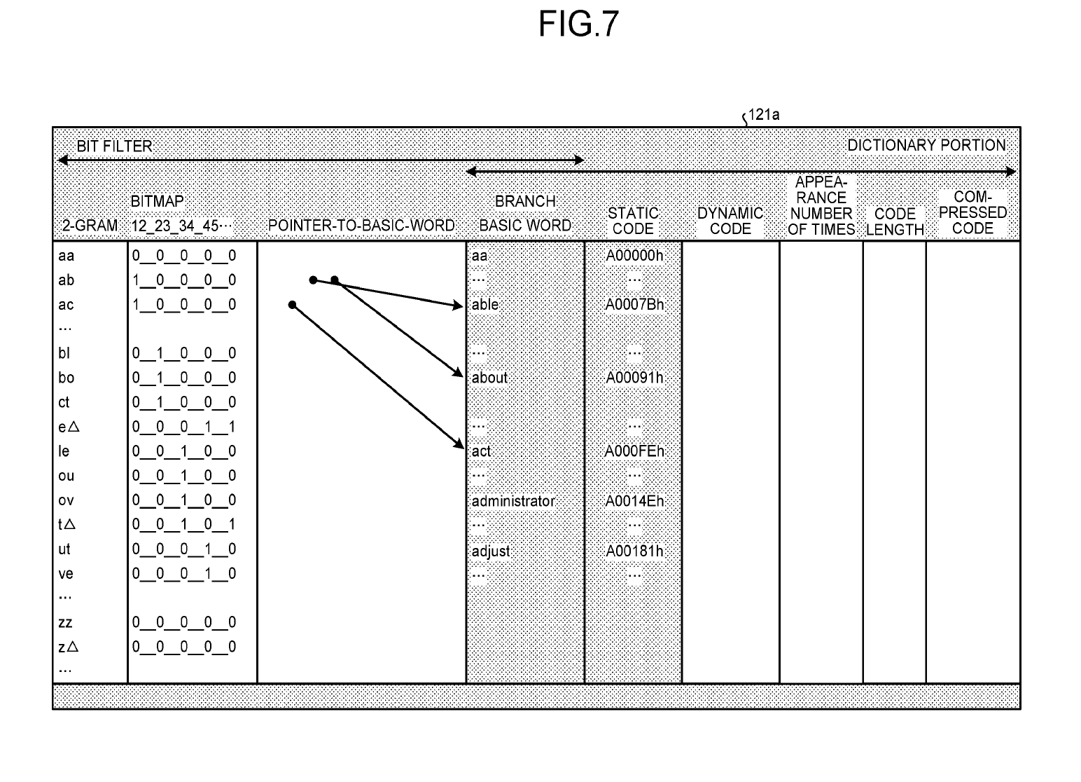

The following describes the compression dictionary 121a in a stage a static code has been allocated to a basic word. FIG. 7 is a first diagram for explaining generation of a compression dictionary. As illustrated in FIG. 7, the compression dictionary 121a associates a basic word with a 2-gram, a bitmap, a static code, a dynamic code, the appearance number of times, a code length, and a compressed code. The “2-gram” (bigram) refers to a group of two consecutive characters included in each word. For example, the word “able” includes 2-grams corresponding to “ab”, “bl”, and “le”.

The “bitmap” represents the position of a 2-gram included in a basic word. For example, when the bitmap for the 2-gram “ab” is “1_0_0_0_0”, the bitmap represents that the first two characters in the basic word is “ab”. Each bitmap is associated with one or more of the basic words by the pointer-to-basic-word. For example, the bitmap “1_0_0_0_0” for the 2-gram “ab” is associated with the words “able” and “about”.

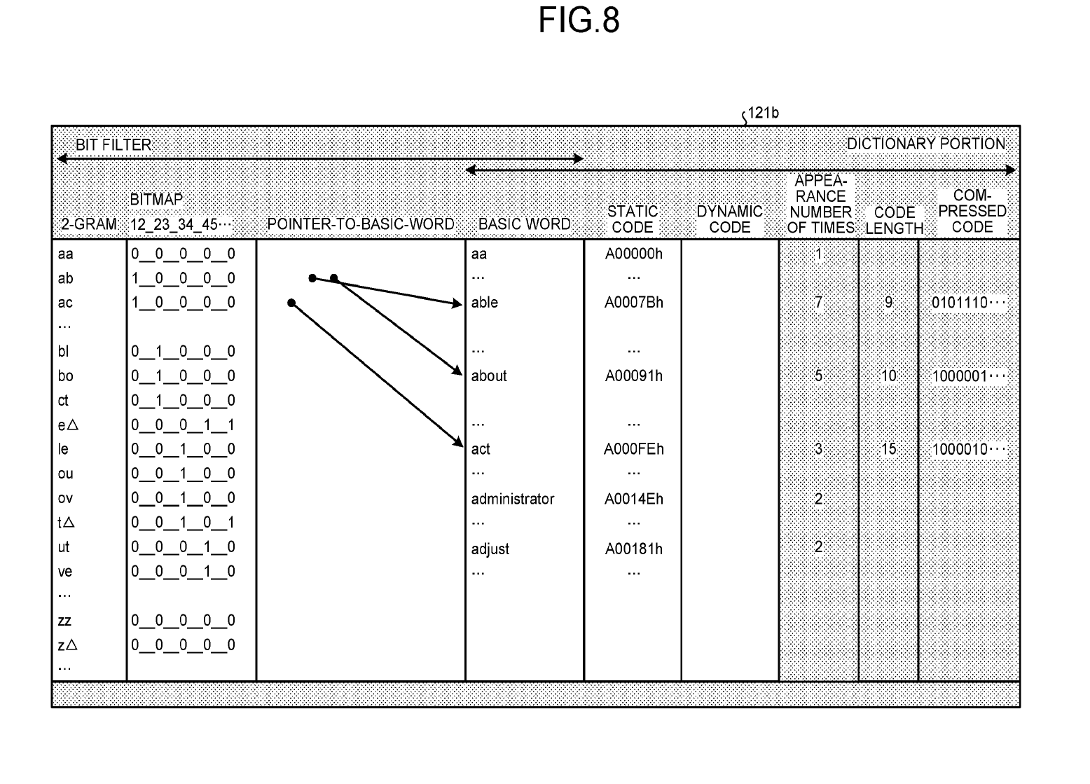

The “basic word” is a word registered on the compression dictionary 121a. For example, the sampling unit 111 registers each of the about 190,000 words extracted from the population on the compression dictionary 121a as a basic word. The “static code” is a 3-byte word code to be uniquely allocated to each basic word. The “dynamic code” is a 16-bit (2-byte) word code to be allocated to each of the low-frequency words that appear in the target file. The “appearance number of times” is the number of times the basic word appears in the population. The “code length” is the length of the compressed code allocated to each basic word. The “compressed code” is the compressed code corresponding to the code length. For example, when the code length of a basic word is “6”, a G-bit compressed code is stored in the “compressed code”. The tallying of the appearance number of times and calculation of the code length will be described in detail later. In an example in FIG. 7, pieces of data in the items are stored as records associated with each other. However, the pieces of data may be stored in a different manner as long as the above-described relation among the items is maintained. This also applies to FIGS. 8 to 10 and FIG. 16.

The first file reader 112 is a processor that reads each text file included in the population and tallies the appearance number of times of each basic word in the population. Firstly, the first file reader 112 reads the text files included in the population sequentially from the top, extracts each of the basic words included in the population, and compares the extracted word with the basic words in the compression dictionary 121a. When the first file reader 112 compares the word extracted from the population with the basic words in the compression dictionary 121a, the first file reader 112 uses a pointer-to-basic-word that associates the basic word with a 2-gram and a bitmap. Every time when the first file reader 112 extracts a word from the population, in the compression dictionary 121a, the first file reader 112 increments the appearance number of times of the basic word corresponding to the word extracted from the population, thereby tallying the appearance number of times of each basic word.

Subsequently, the first file reader 112 calculates the appearance frequency of each word based on the tallied appearance number of times of each word and outputs the result to the dictionary-generating unit 113. For example, the first file reader 112 divides the appearance number of times of each word by the total value of the appearance number of times of all of the words, thereby calculating the appearance frequency of each word.

If the first file reader 112 extracts a word not registered on the compression dictionary 121a from the target file, the first file reader 112 increments the appearance frequency of each character included in the extracted word, in a character-and-symbol portion 121d. For example, if the dictionary-generating unit 113 extracts the word “repertoire” not registered on the compression dictionary 121a, the first file reader 112 increments the appearance number of times of each of the alphabetical characters “r”, “e”, “p”, “e”, “r”, “t”, “o”, “i”, “r”, and “e” in the character-and-symbol portion 121d. The character-and-symbol portion 121d will be described in detail later.

The dictionary-generating unit 113 is a processor that generates a compression dictionary 121b by registering thereon the compressed code corresponding to the appearance frequency of each high-frequency word, associated with the high-frequency word. The dictionary-generating unit 113 calculates the code length for the high-frequency words positioned from rank 1 to 8,000 in the ordinal rank of the appearance frequency out of the words registered on the compression dictionary 121b. For example, the dictionary-generating unit 113 calculates the code length n for a high-frequency word by substituting the appearance frequency x of the basic word in the population into Expression (1). Subsequently, the dictionary-generating unit 113 allocates the variable-length code corresponding to the calculated code length n to the basic word. The dictionary-generating unit 113 then registers the allocated variable-length code associated with the basic word on the compression dictionary 121a. The dictionary-generating unit 113 may specify the code length n in any other method than that by using Expression (1).

n=log₂(1/x) (1)

The following describes the compression dictionary 121b in a stage a variable-length code has been allocated. FIG. 8 is a second diagram for explaining the generation of the compression dictionary. As illustrated in FIG. 8, the compression dictionary 121b associates the basic word with the 2-gram, the bitmap, the static code, the dynamic code, the appearance number of times, the code length, and the compressed code. The elements of the compression dictionary 121b are the same as those in the compression dictionary 121a, and the descriptions thereof are therefore omitted.

The dictionary-generating unit 113 allocates appropriate code lengths to the high-frequency words “able”, “about”, and “act”, for example, by using Expression (1). For example, the dictionary-generating unit 113 obtains the code length “9” based on the appearance number of times of the high-frequency word “able”, that is, “7”. The dictionary-generating unit 113 allocates the variable-length code corresponding to the calculated code length “9”, that is, “0101110 . . . ” to the word “able”. For example, the dictionary-generating unit 113 obtains the code length “10” based on the appearance number of times of the high-frequency word “about”, that is, “5”. The dictionary-generating unit 113 allocates the variable-length code corresponding to the calculated code length “10”, that is, “1000001 . . . ” to the word “about”. For example, the dictionary-generating unit 113 obtains the code length “15” based on the appearance number of times of the high-frequency word “act”, that is, “3”. The dictionary-generating unit 113 allocates the variable-length code corresponding to the calculated code length “15”, that is, “1000010 . . . ” to the word “act”.

If a code length larger than 16 bits is allocated to a high-frequency word, the dictionary-generating unit 113 can correct the code length of the high-frequency word. For example, if a code length of 18 bits is allocated to a high-frequency word, the dictionary-generating unit 113 can correct the code length to 1 to 16 bits.

The second file reader 114 is a processor that reads the target file. The second file reader 114 reads the target file and extracts words. The second file reader 114 outputs each of the extracted words to the determination unit 115.

If one of the words extracted by the second file reader 114 is registered on the compression dictionary 121b as a basic word, the determination unit 115 determines whether the compressed code corresponding to the extracted word is registered on the compression dictionary. The determination unit 115 determines whether one of the words extracted by the second file reader 114 is registered on the compression dictionary 121b as a basic word. If one of the extracted words is registered on the compression dictionary 121b as a basic word, the determination unit 115 executes the following process.

The determination unit 115 compares the word extracted from the target file with the basic word, and determines whether the compressed code corresponding to the extracted word is registered on the compression dictionary 121b. If the compressed code corresponding to the extracted word is registered on the compression dictionary 121b, the determination unit 115 acquires the compressed code corresponding to the extracted word from the compression dictionary 121b. The determination unit 115 outputs the acquired compressed code to the file writer 118.

If one of the words extracted from the target file is registered on the compression dictionary 121b but the compressed code corresponding to the extracted word is not registered on the compression dictionary 121b, the determination unit 115 outputs the extracted word to the word-encoding unit 116. The word-encoding unit 116 allocates a dynamic code to the output word. The dynamic code is a 16-bit (2-byte) fixed-length code to be allocated to appropriate words in the order of registration on the compression dictionary 121b. For example, the word-encoding unit 116 allocates dynamic codes “A000h”, “A001h”, “A002h”, “A003h” . . . to each word as the dynamic codes. The word-encoding unit 116 registers the allocated dynamic code associated with the basic word on the compression dictionary 121b. The word-encoding unit 116 then outputs the dynamic code registered on the compression dictionary 121b to the compressed file.

As described above, the compression unit 110 allocates 16-bit dynamic codes to the low-frequency words extracted from the target file, registers them on the compression dictionary 121b, and outputs the registered dynamic codes to the compressed file, thereby executing the compression process through one pass. That is, the compression unit 110 executes the registration process of the dynamic codes in parallel with the compression process of the files. Hereinafter, the following process may be called “one-pass compression process”: the compression unit 110 allocates dynamic codes to the low-frequency words, registers them on the compression dictionary 121, and outputs the allocated dynamic codes to the compressed file 125.

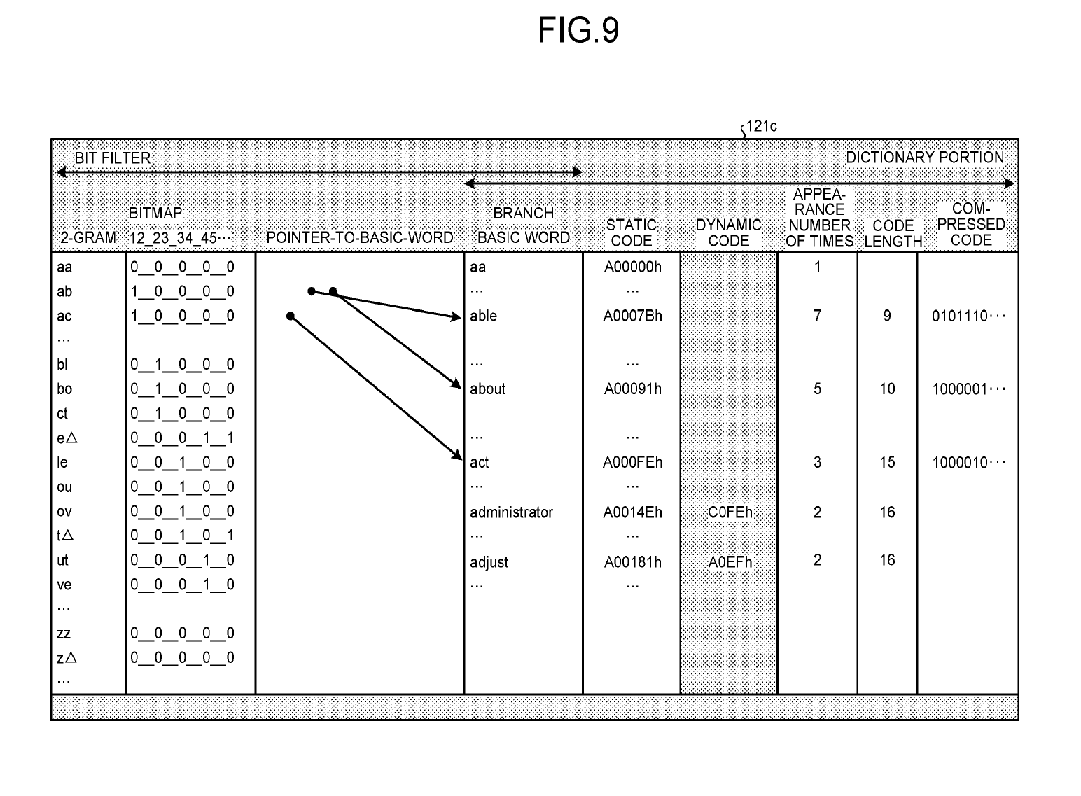

The following describes a compression dictionary 121c in a stage a dynamic code has been allocated to a low-frequency word. FIG. 9 is a third diagram for explaining generation of the compression dictionary. As illustrated in FIG. 9, the compression dictionary 121c associates the basic word with the 2-gram, the bitmap, the static code, the dynamic code, the appearance number of times, the code length, and the compressed code. The elements of the compression dictionary 121c are the same as those in the compression dictionary 121a, and the descriptions thereof are therefore omitted.

For example, the word-encoding unit 116 allocates a dynamic code “C0FEh” to a low-frequency word “administrator” extracted from the target file and registers it on the compression dictionary 121c. The word-encoding unit 116 then outputs the dynamic code “C0FEh” registered on the compression dictionary 121c to the file writer 118. The word-encoding unit 116 also allocates a dynamic code “A0EFh” to a low-frequency word “adjust” extracted from the target file and registers it on the compression dictionary 121c. The word-encoding unit 116 then outputs the dynamic code “A0EFh” registered on the compression dictionary 121c to the file writer 118.

If one of the words extracted from the target file by the second file reader 114 is not registered on the compression dictionary 121b as a basic word, the determination unit 115 executes the following process. The determination unit 115 outputs the word extracted from the target file to the character-encoding unit 117. The character-encoding unit 117 increments the appearance number of times of each character or each symbol included in the extracted word. The character-and-symbol portion 121d is an area for storing therein the compressed codes each corresponding to the characters and symbols secured in the compression dictionary 121. The character-encoding unit 117 allocates the code length to each of the characters and symbols based on the appearance number of times of the characters and symbols in the same manner as the word-encoding unit 116 allocating the code length to the words. Subsequently, the character-encoding unit 117 allocates a variable-length code or a fixed-length code to the characters and symbols based on the code length allocated by the character-encoding unit 117. The character-encoding unit 117 then registers the variable-length code or the fixed-length code allocated to the characters and symbols, associated with the characters and symbols on the character-and-symbol portion 121d.

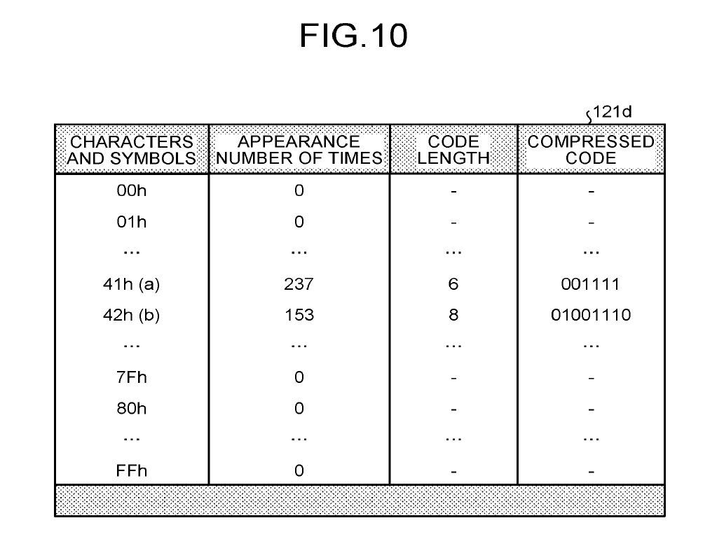

The following describes an example of the character-and-symbol portion 121d. FIG. 10 is a diagram for explaining the character-and-symbol portion of the compression dictionary. As illustrated in FIG. 10, the character-and-symbol portion 121d in the compression dictionary associates the characters and symbols with the appearance number of times, the code length, and the compressed code. The “character-and-symbol” is a character code of alphabetical characters, numeric characters, special characters, and control characters, for example, included in the target file. In FIG. 10, the ASCII code is stored, but other character codes may be stored. The “appearance number of times” is the number of times the characters and symbols appear in the target file. The “code length” is the length of the compressed code allocated to the characters and symbols. The “code length” is obtained by, for example, substituting the “appearance number of times” into Expression (1). The “compressed code” is the compressed code allocated to the characters and symbols. The “compressed code” corresponds to the code length.

The file writer 118 is a processor that generates the compressed file 125. The file writer 118 generates compressed data 126 based on the compressed codes output from the word-encoding unit 116 and the character-encoding unit 117. The file writer 118 stores the generated compressed data 126 in the compressed file 125.

The file writer 118 acquires each high-frequency word and the appearance number of times from the compression dictionary 121c. Subsequently, the file writer 118 registers the acquired high-frequency word associated with the acquired appearance number of times on the frequency table 127. In this manner, the file writer 118 generates the frequency table 127 in which each high-frequency word is associated with the appearance number of times. The file writer 118 stores the generated frequency table in the compressed file 125. The file writer 118 may store the static code corresponding to the high-frequency word instead of the high-frequency word itself in the frequency table 127.

The file writer 118 acquires each of the low-frequency words registered on the compression dictionary 121c. The file writer 118 registers the low-frequency words on the dynamic dictionary 128 so that the offsets of the low-frequency words increase in the ascending order they are registered. For example, the low-frequency words “average”, “visitor”, and “atmosphere” are registered on the compression dictionary 121c in this order. The file writer 118 sequentially registers the low-frequency words “average”, “visitor”, and “atmosphere” on the dynamic dictionary 128 in this order so that their offsets increase in this order, thereby generating the dynamic dictionary 128. The file writer 118 stores the generated dynamic dictionary 128 in the compressed file 125. The file writer 118 may store the static code corresponding to the low-frequency word instead of the low-frequency word itself in the dynamic dictionary 128.

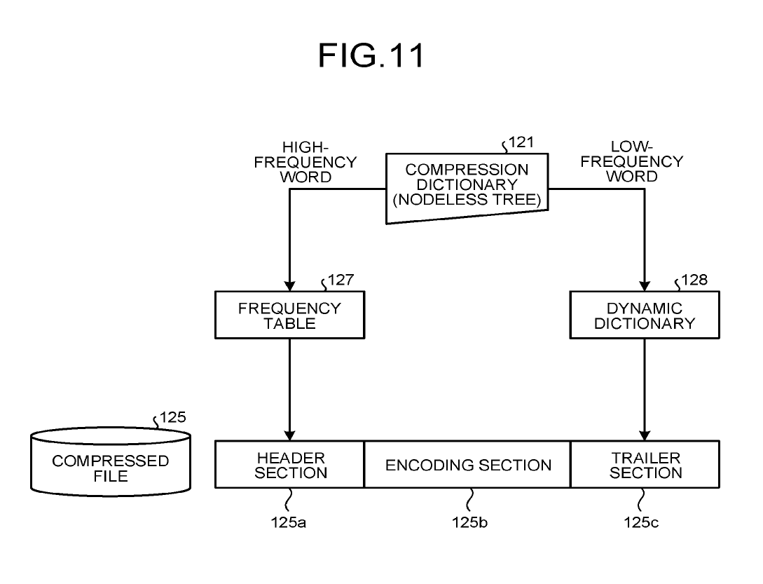

The following describes a process executed by the file writer 118 with reference to FIG. 11. FIG. 11 is a second diagram for explaining the compression according to the first embodiment. The file writer 118 acquires each high-frequency word and the appearance number of times from the compression dictionary (a nodeless tree) 121. The file writer 118 sequentially registers the acquired high-frequency word associated with the acquired appearance number of times on the frequency table 127, thereby generating the frequency table 127. The file writer 118 stores the generated frequency table 127 in a header section 125a in the compressed file 125.

The file writer 118 acquires each of the low-frequency words registered on the compression dictionary (the nodeless tree) 121. The file writer 118 sequentially registers the low-frequency words on the dynamic dictionary 128 so that the offsets of the low-frequency words increase in the ascending order they are registered, thereby generating the dynamic dictionary 128. The file writer 118 stores the generated dynamic dictionary 128 in a trailer section 125c in the compressed file 125.

The file writer 118 outputs the compressed data to an encoding section 125b in the compressed file 125.

Entire Flowchart of Compression Process

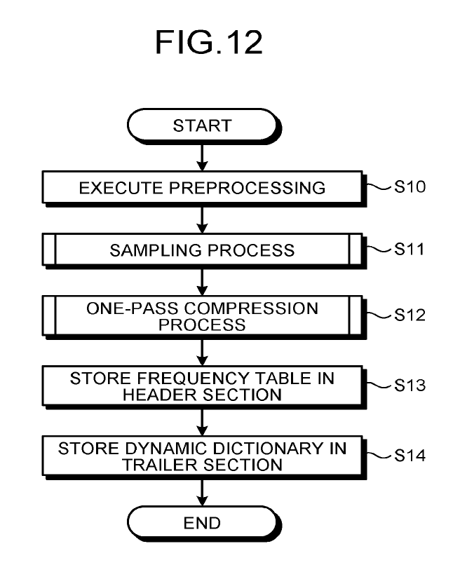

The following describes a flowchart illustrating the entire flow of the compression process. FIG. 12 is a flowchart for explaining the entire flow of the compression process. As illustrated in FIG. 12, the compression unit 110 executes preprocessing (Step S10). For example, in the preprocessing, the compression unit 110 secures a storage area for storing therein the compression dictionary 121a and a storage area for storing therein the compressed file 125. The compression unit 110 executes a sampling process, that is, extracts 190,000 words from the population, and then allocates appropriate compressed codes to the high-frequency words positioned from rank 1 to 8,000 in the appearance order out of the extracted 190,000 words (Step S11).

As described above, the compression unit 110 allocates compressed codes to the low-frequency words extracted from the target file, and generates the compressed file 125, thereby executing the one-pass compression process (Step S12). The compression unit 110 generates the frequency table 127 based on the compression dictionary 121 and stores the generated frequency table 127 in the header section 125a in the compressed file 125 (Step S13). The frequency table 127 includes the high-frequency words and the appearance number of times. The compression unit 110 generates the dynamic dictionary 128 based on the compression dictionary 121 and stores the generated dynamic dictionary 128 in the trailer section 125c in the compressed file 125 (Step S14). The low-frequency words are registered on the dynamic dictionary 128 so that their offsets increase in the ascending order they are registered on the compression dictionary 121c. The flows at Steps S11 and S12 will be described in detail later.

Flowchart of Sampling Process

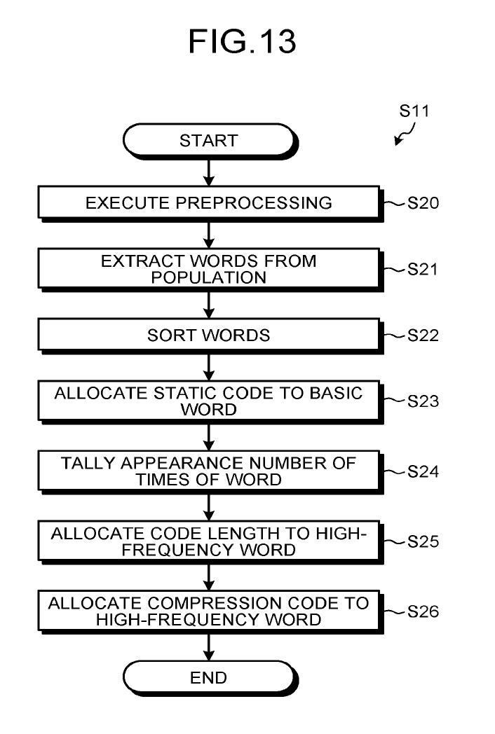

The following describes a process flow at Step S11 in detail. FIG. 13 is a flowchart illustrating an example of the flow of a sampling process. As illustrated in FIG. 13, the compression unit 110 executes preprocessing (Step S20). For example, in the preprocessing, the compression unit 110 secures a working area for generating the compression dictionary 121b. The sampling unit 111 extracts words from the population (Step S21). For example, the sampling unit 111 sorts the words extracted from the population in the alphabetical order and registers them on the compression dictionary 121 as basic words (Step S22). The sampling unit 111 allocates a static code to each of the registered basic words (Step S23).

The first file reader 112 reads the text files included in the population and tallies the appearance number of times of each basic word in the population (Step S24). The dictionary-generating unit 113 allocates a 1- to 16-bit code length to each high-frequency word based on the appearance frequency of each high-frequency word (Step S25). The dictionary-generating unit 113 allocates a compressed code (a variable-length code) to each high-frequency word based on the code length allocated to the high-frequency word (Step S26).

Flowchart of One-Pass Compression Process

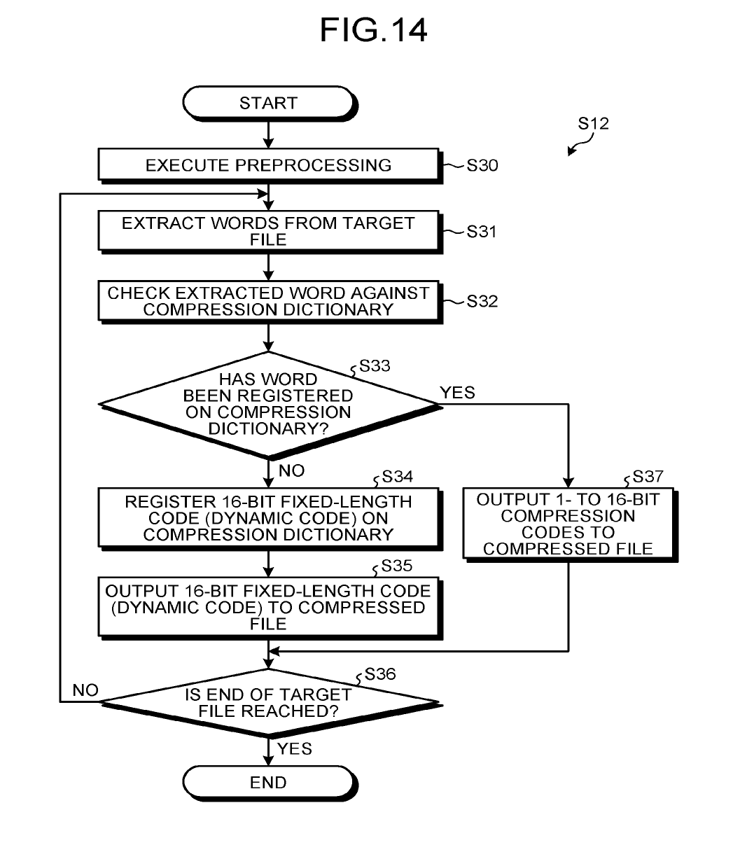

The following describes a process flow at Step S12 in detail. FIG. 14 is a flowchart illustrating an example of the flow of the one-pass compression process. As illustrated in FIG. 14, the compression unit 110 executes preprocessing (Step S30). For example, in the preprocessing, the compression unit 110 secures a working area for executing the one-pass compression process. The second file reader 114 extracts words from the target file (Step S31).

The determination unit 115 checks the words extracted from the target files by the second file reader 114 against the compression dictionary 121 (Step S32). The determination unit 115 determines whether one of the words extracted from the target file has been registered on the compression dictionary 121 (Step S33). If one of the words extracted from the target file has been registered on the compression dictionary 121 (Yes at Step S33), the file writer 118 acquires 1- to 16-bit compressed codes corresponding to the words from the compression dictionary 121, and outputs the compressed codes to the compressed file 125 (Step S37). The compression unit 110 then moves the process sequence to Step S36.

If one of the extracted words has not been registered on the compression dictionary 121 (No at Step S33), the word-encoding unit 116 associates a 16-bit fixed-length code (a dynamic code) with the basic word and registers them on the compression dictionary 121 as a low-frequency word (Step S34). For example, the word-encoding unit 116 allocates 16-bit fixed-length codes in the ascending order, like A000h, A001h, A002h . . . , for example, to the words in the order of extraction. The file writer 118 outputs 16-bit fixed-length codes (the dynamic codes) registered on the compression dictionary 121 to the compressed file 125 (Step S35). The compression unit 110 then moves the process sequence to Step S36.

At Step S36, the compression unit 110 determines whether the end of the target file is reached (Step S36). If the end of the target file is reached (Yes at Step S36), the compression unit 110 ends the process. If the end of the target file is not yet reached (No at Step S36), the compression unit 110 returns the process sequence to Step S31.

As described above, according to the first embodiment, a code length of 2 bytes or larger is prevented from being allocated to low-frequency words, thereby improving the code lengths allocated to the low-frequency words.

### Configuration of Processors Related to Expansion Process According to First Embodiment

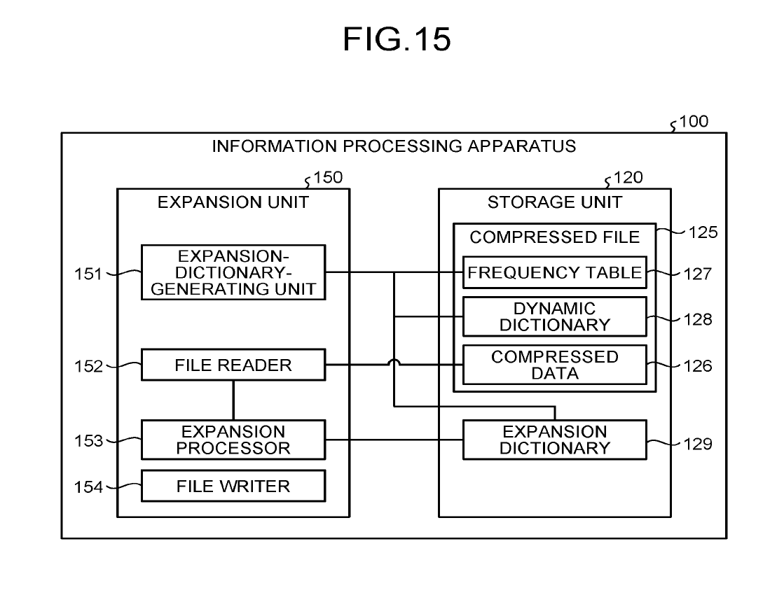

The following describes the system configuration of an expansion process according to the first embodiment with reference to FIG. 15. FIG. 15 is a diagram illustrating an example of the system configuration of the expansion process according to the first embodiment. As illustrated in FIG. 15, the information processing apparatus 100 includes the expansion unit 150 and the storage unit 120. The expansion unit 150 includes an expansion-dictionary-generating unit 151, a file reader 152, an expansion processor 153, and a file writer 154. The storage unit 120 includes the compressed file 125 and an expansion dictionary 129. The compressed file 125 includes the compressed data 126, the frequency table 127, and the dynamic dictionary 128. The following describes in detail processors in the expansion unit 150.

The expansion-dictionary-generating unit 151 is a processor that generates the expansion dictionary 129 based on the frequency table 127 and the dynamic dictionary 128. Firstly described is a procedure to register a high-frequency word on the expansion dictionary 129. The expansion-dictionary-generating unit 151 acquires the appearance number of times of each high-frequency word from the frequency table 127. The expansion-dictionary-generating unit 151 calculates the code length of each high-frequency word based on the appearance number of times of each acquired high-frequency word. The expansion-dictionary-generating unit 151 allocates the compressed code corresponding to the calculated code length to each high-frequency word and registers them on the expansion dictionary 129.

The following describes a procedure to register a low-frequency word on the expansion dictionary 129. The low-frequency words are registered on the dynamic dictionary 128 so that their offsets increase in the ascending order they are registered on the compression dictionary 121. The expansion-dictionary-generating unit 151 allocates dynamic codes “A000h”, “A001h”, “A002h” . . . in this order to the low-frequency words registered on the compression dictionary 121 in the ascending order of offsets.

For example, the low-frequency words “average”, “visitor”, and “atmosphere” . . . are registered on the compression dictionary 121 in the ascending order of offsets. The expansion-dictionary-generating unit 151 allocates “A000h” to “average”, “A001h” to “visitor”, and “A002h” to “atmosphere”.

The expansion-dictionary-generating unit 151 registers the dynamic code allocated to each low-frequency word on the expansion dictionary 129. In this manner, the expansion dictionary 129 is generated.

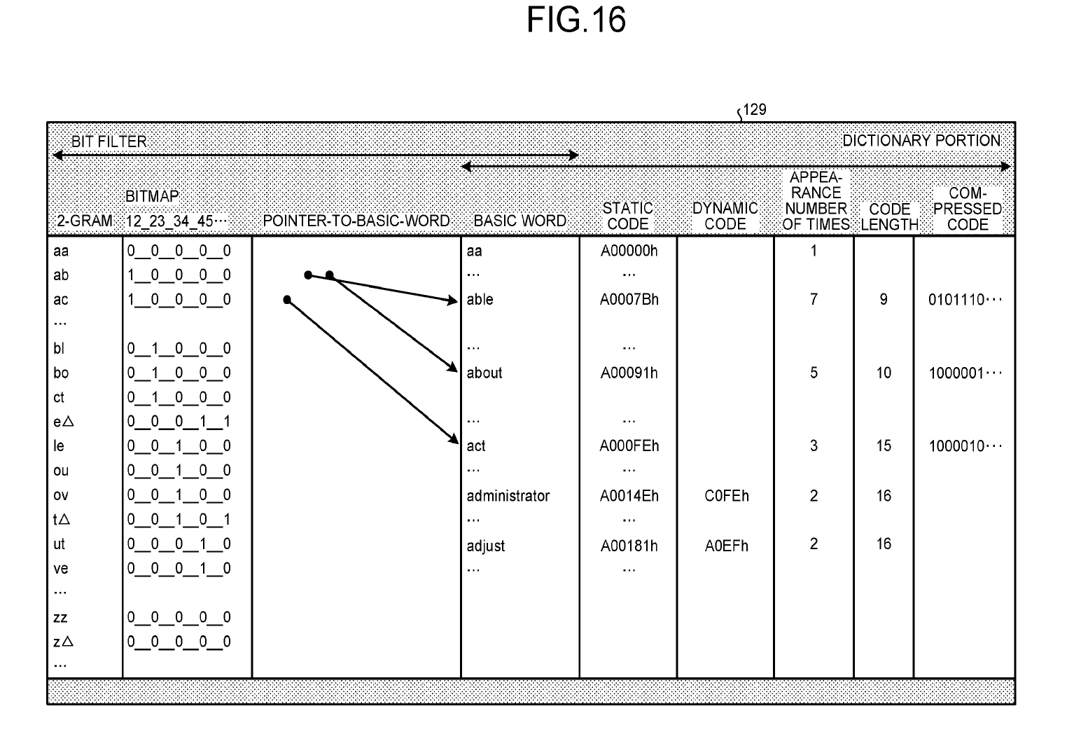

The following describes an example of the expansion dictionary 129. FIG. 16 is a diagram for explaining the expansion dictionary. As illustrated in FIG. 16, the expansion dictionary 129 associates the basic word with the 2-gram, the bitmap, the static code, the dynamic code, the appearance number of times, the code length, and the compressed code. The “basic word” is a word registered on the expansion dictionary 129. The “static code” is allocated to each basic word based on the frequency table 127 or the dynamic dictionary 128. The “dynamic code” is allocated to each low-frequency word based on the dynamic dictionary 128. The “appearance number of times” is data acquired from the frequency table 127. The “code length” is calculated by the expansion-dictionary-generating unit 151 based on the appearance number of times. The “compressed code” is allocated by the expansion-dictionary-generating unit 151 based on the code length.

The file reader 152 is a processor that acquires a certain length of compressed code from the compressed data 126. The file reader 152 acquires a 16-bit compressed code from the compressed data 126 and outputs it to the expansion processor 153.

The expansion processor 153 is a processor that expands the compressed code output from the file reader 152. The expansion processor 153 retrieves the 16-bit compressed code output by the file reader 152 from the expansion dictionary 129 and identifies the basic word corresponding to the compressed code. The expansion processor 153 also identifies the code length corresponding to the basic word. For example, as illustrated in FIG. 16, if the compressed code is “1000001 . . . ”, in the expansion dictionary 129, the expansion processor 153 identifies the basic word “about” corresponding to the compressed code “1000001 . . . ” and identifies the code length “10”.

If the code length is “10”, the 1st to 10th bits out of the 16 bits of the compressed code acquired by the file reader 152 represent the compressed code corresponding to the basic word “about”. The 11th to 16th bits out of the 16 bits of the compressed code acquired by the file reader 152 represent the compressed code corresponding to the basic word to be expanded next.

The file writer 154 is a processor that writes the basic word identified by the expansion processor 153 on the expansion file.

The file writer 154 also outputs the code length identified by the expansion processor 153 to the file reader 152. The file reader 152 identifies the position at which the compressed code is acquired next in the compressed data 126 in accordance with the output code length. For example, if the code length output by the file writer 154 is “10”, the file reader 152 acquires 16 bits of the compressed code from the position 10 bits later from the position at which the compressed code is acquired last time.

The process for expanding characters and symbols is the same as that for expanding words, and the descriptions thereof are therefore omitted.

Process Flow of Generating Expansion File

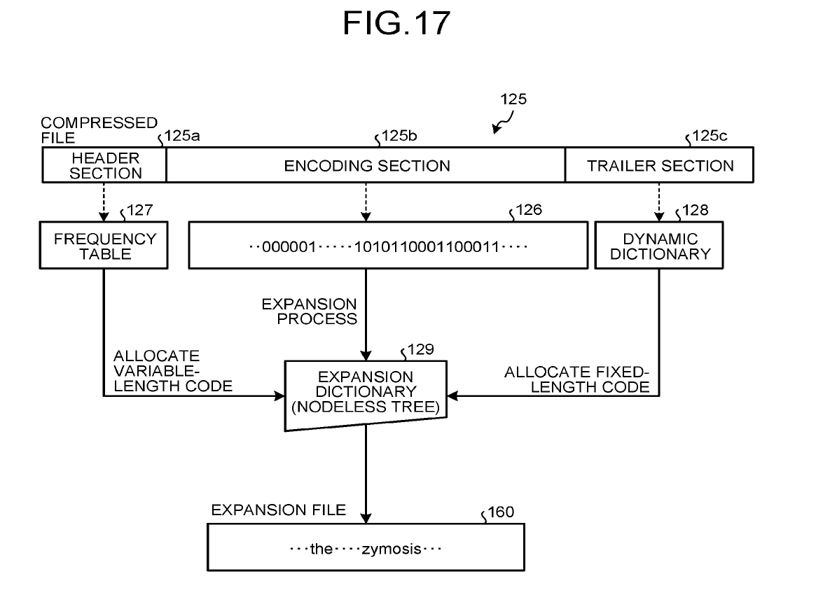

The following describes the process flow of generating an expansion file with reference to FIG. 17. FIG. 17 is a diagram for explaining expansion according to the first embodiment. The expansion unit 150 executes the process for generating the expansion dictionary 129 and executes the process for expanding the compressed file based on the generated expansion dictionary 129.

The process for generating the expansion dictionary will be firstly described. The expansion-dictionary-generating unit 151 acquires the appearance number of times of each high-frequency word from the frequency table 127 stored in the header section 125a in the compressed file 125. The expansion-dictionary-generating unit 151 calculates the code length of each high-frequency word based on the appearance number of times of each acquired high-frequency word. Subsequently, the expansion-dictionary-generating unit 151 registers the calculated code length on the expansion dictionary 129. The expansion-dictionary-generating unit 151 then allocates the variable-length code to the high-frequency word based on the registered code length and registers the variable-length code and the code length on the expansion dictionary 129.

For example, the expansion-dictionary-generating unit 151 obtains the code length “6” based on the appearance number of times of the high-frequency word “the”. The expansion-dictionary-generating unit 151 allocates the variable-length code “000001” corresponding to the code length “6” to the high-frequency word the and registers the variable-length code “000001” and the code length “6” on the expansion dictionary 129.

The expansion-dictionary-generating unit 151 acquires low-frequency words in the order of registration on the dynamic dictionary 128, from the dynamic dictionary 128 stored in the trailer section 125c in the compressed file 125. The expansion-dictionary-generating unit 151 allocates a 16-bit dynamic code to each low-frequency word and registers the dynamic code and the code length on the expansion dictionary 129. In this manner, the expansion-dictionary-generating unit 151 generates the expansion dictionary 129.

For example, the expansion-dictionary-generating unit 151 acquires the word “zymosis” from the dynamic dictionary 128 and registers the dynamic code “1010110001100010” and the code length “16” on the expansion dictionary 129 based on the rank of registration of “zymosis” on the dynamic dictionary. In this manner, the expansion unit 150 executes the process for generating the expansion dictionary 129.

The following describes the process for expanding the compressed file based on the expansion dictionary 129. The file reader 152 acquires a 16-bit compressed code from the compressed data 126 and outputs it to the expansion processor 153. For example, the file reader 152 acquires “1010110001100010” from the compressed data 126 and outputs it to the expansion processor 153.

The expansion processor 153 checks the output 16-bit compressed code against the expansion dictionary (the nodeless tree) 129 and identifies the basic word and the code length corresponding to the compressed code. For example, the expansion processor 153 identifies the basic word “zymosis” and the code length “16” corresponding to the output “1010110001100010”.

The expansion processor 153 outputs the identified basic word to the file writer 154. The file writer 154 outputs the output basic word to an expansion file 160.

The expansion processor 153 also outputs the identified code length to the file reader 152. The file reader 152 identifies the position at which the compressed data 126 is read next in accordance with the output code length. For example, if the code length output by the expansion processor 153 is “16”, the file reader 152 identifies the position 16 bits later from the position at which the compressed data is read last time as the position at which the compressed data is read next.

Flowchart of Expansion Process

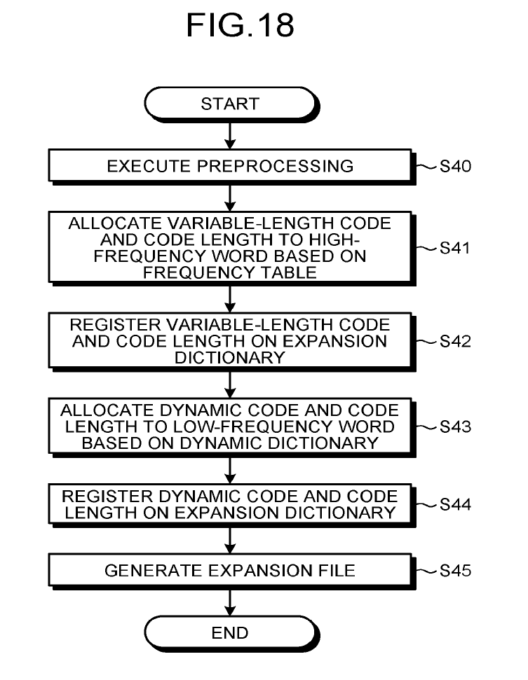

The following describes a flowchart illustrating the flow of the expansion process. FIG. 18 is a flowchart illustrating the flow of expanding the compressed code. As illustrated in FIG. 18, the expansion unit 150 executes preprocessing (Step S40). For example, the expansion unit 150 secures a storage area for storing therein the expansion dictionary 129 and a working area for generating the expansion dictionary 129. The expansion-dictionary-generating unit 151 allocates a variable-length code and a code length to each high-frequency word based on the frequency table 127 (Step S41). The expansion-dictionary-generating unit 151 registers the variable-length code and the code length on the expansion dictionary 129 (Step S42). The expansion-dictionary-generating unit 151 allocates a dynamic code and a code length to each low-frequency word based on the dynamic dictionary 128 (Step S43). The expansion-dictionary-generating unit 151 registers the dynamic code and the code length on the expansion dictionary 129 (Step S44). The expansion processor 153 and the file writer 154 execute the expansion process on the target file by using the generated expansion dictionary 129, thereby generating the expansion file (Step S45).

Extension of Low-Frequency Word Area

If the target file includes 32,000 or more words, the compression unit 110 can extend the area for storing therein the low-frequency words. Hereinafter, the area for storing therein the low-frequency words is called a low-frequency word area.

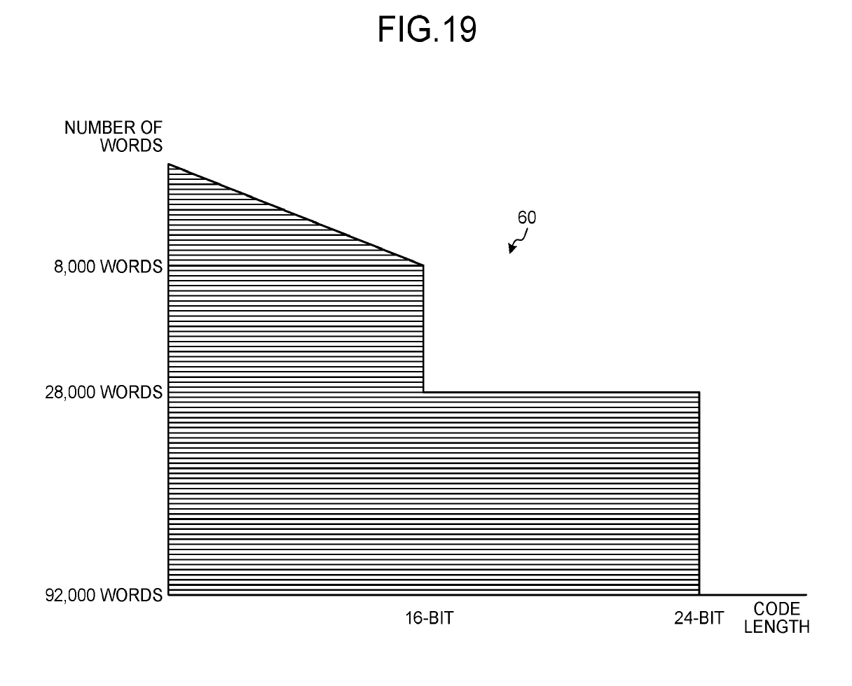

FIG. 19 is a diagram for explaining extension of the low-frequency word area. A graph 60 represents the code lengths to be allocated to the basic words when the low-frequency word area is extended. The vertical axis of the graph 60 represents the number of words. The smaller number of words indicates a higher appearance frequency in the population, and the larger number of words indicates a lower appearance frequency. That is, the number of words represents the appearance order of the words in the population. The high-frequency words are located at the position from 1 to 8,000 words along the vertical axis in the graph 60. The low-frequency words positioned from rank 8,000 to 28,000 in the ordinal rank of the appearance frequency are located at the position from 8,000 to 28,000 words along the vertical axis in the graph 60. The low-frequency words positioned from rank 28,000 to 92,000 in the ordinal rank of the appearance frequency are located at the position from 28,000 to 92,000 words along the vertical axis in the graph 60.

The horizontal axis represents the code length allocated to each of the words. For example, 1- to 16-bit variable-length codes are allocated to the high-frequency words. 16-bit fixed-length codes are allocated to the low-frequency words positioned from rank 8,000 to 28,000 in the ordinal rank of the appearance. 24 bits of fixed-length codes are allocated to the low-frequency words positioned from rank 28,000 to 92,000 in the ordinal rank of the appearance.

The following describes an area of the compressed code allocated to each word. The area from 0000h to 9FFFh is allocated to the high-frequency words. The area from A0000 to EFFFFh is allocated to the low-frequency words positioned from rank 8,000 to 28,000 in the ordinal rank of the appearance. The area from F00000 to FFFFFFh is allocated to the low-frequency words positioned from rank 28,000 to 92,000 in the ordinal rank of the appearance. As described above, the compression unit 110 extends the low-frequency word area, thereby registering about 60,000 additional words as low-frequency words on the compression dictionary. As a result, the compression unit 110 can allocate the compressed code to each word if the target file has a large capacity.

### Advantageous Effects

As described above, when encoding a first file included in a plurality of files in accordance with a code allocation rule generated from information on frequency of words in the files, the compression unit 110 encodes each word having its appearance frequency in the information on frequency larger than that of a word positioned at a given ordinal rank. The compression unit 110 encodes at least some of the words having their appearance frequencies in the information on frequency smaller than that of the word positioned at the given ordinal rank in accordance with a code allocation rule with codes different from those of the code allocation rule for the above-described encoding, by using a first code length. This operation can achieve reduction in the code length of the compressed code allocated to a word during the compression process, thereby improving the compression rate.

The first code length is equal to or larger than the maximum coding length of the words to be encoded in accordance with the code allocation rule. This configuration can extend the area for storing therein the words having low appearance frequencies in the compression dictionary.

The compression unit 110 allocates a compressed code of a given length to each word having its appearance frequency larger than that of the word positioned at a second given ordinal rank out of the words having their appearance frequencies smaller than that of the word positioned at the given ordinal rank. The compression unit 110 encodes each word having its appearance frequency smaller than that of the word positioned at the second given ordinal rank by using a second code length different from the given code length. This operation can allocate the compressed code to each word even if the target file to be encoded has a large capacity.

The compression unit 110 allocates a variable-length compressed code having a length equal to or smaller than a given length to each of the words positioned at a given ordinal rank or above of the appearance frequency in the target file in accordance with the appearance frequency. The compression unit 110 allocates a compressed code of a given length to each of the words positioned below the given ordinal rank of the appearance frequency. The compression unit 110 compresses the target file by using the compressed codes allocated to the words. This operation can achieve reduction in the code length of the compressed code allocated to a word during the compression process, thereby improving the compression rate.

The compression unit 110 causes a computer to execute the process for acquiring a plurality of words from the population including one or more files. The compression unit 110 allocates the compressed code to each of the words included in the target file out of the words acquired from the population. This operation can achieve reduction in the time to spend for the compression process.

When allocating compressed codes to a given number of words or more, the compression unit 110 allocates a compressed code of a given length to each of the words positioned at a given ordinal rank or above of the appearance frequency out of the words positioned at another given ordinal rank or below of the appearance frequency. The compression unit 110 allocates a compressed code of another given length to each of the words positioned under another given ordinal rank of the appearance frequency. This operation can extend the area for storing therein the words having low appearance frequencies in the compression dictionary.

The expansion unit 150 generates a dictionary in which the words included in the compressed file are associated with the variable- or the fixed-length compressed code allocated to the words based on the appearance frequency of the words. The expansion unit 150 executes a process for expanding the compressed codes included in the compressed file into the words by using the dictionary. This operation can expand the compressed file including the variable-length code and the fixed-length code.

### Other Aspects Related to First Embodiment

The following describes example modifications according to the above-described embodiment. Modifications are not limited to these described below and any changes and modifications in design can be made as appropriate in the present invention without departing from the spirit and scope of the present invention.

In the first embodiment, the sampling unit 111 collects basic words from the population including a plurality of text files, but this is not limiting. The sampling unit 111 may collect basic words from a single text file.

In the first embodiment, the dictionary-generating unit 113 allocates the 16-bit fixed-length compressed codes to the low-frequency words, but this is not limiting. The dictionary-generating unit 113 may allocate different numbers of bits to the low-frequency words other than 16 bits.

In the first embodiment, the dictionary-generating unit 113 allocates the variable-length codes to the words positioned at rank 8,000 or above in the appearance order, and allocates the fixed-length codes to the words positioned under rank 8,000 in the appearance order, but this is not limiting. The dictionary-generating unit 113 may allocate the variable-length codes or the fixed-length codes to the words by using a borderline of the appearance order other than the rank 8,000.

The target of the compression process may also be monitoring messages output from the system, for example, in addition to the data in a file. For example, a process is executed in which monitoring messages sequentially stored in a buffer are compressed through the above-described compression process, and stored as a log file. For another example, the compression may be made page by page in a database. The compression may also be made in units of a plurality of pages in the database.

The processing procedure, the controlling procedure, the specific names, various types of information including data and parameters described in the first embodiment can be changed as appropriate unless otherwise specified.

Hardware Configuration of Information Processing Apparatus

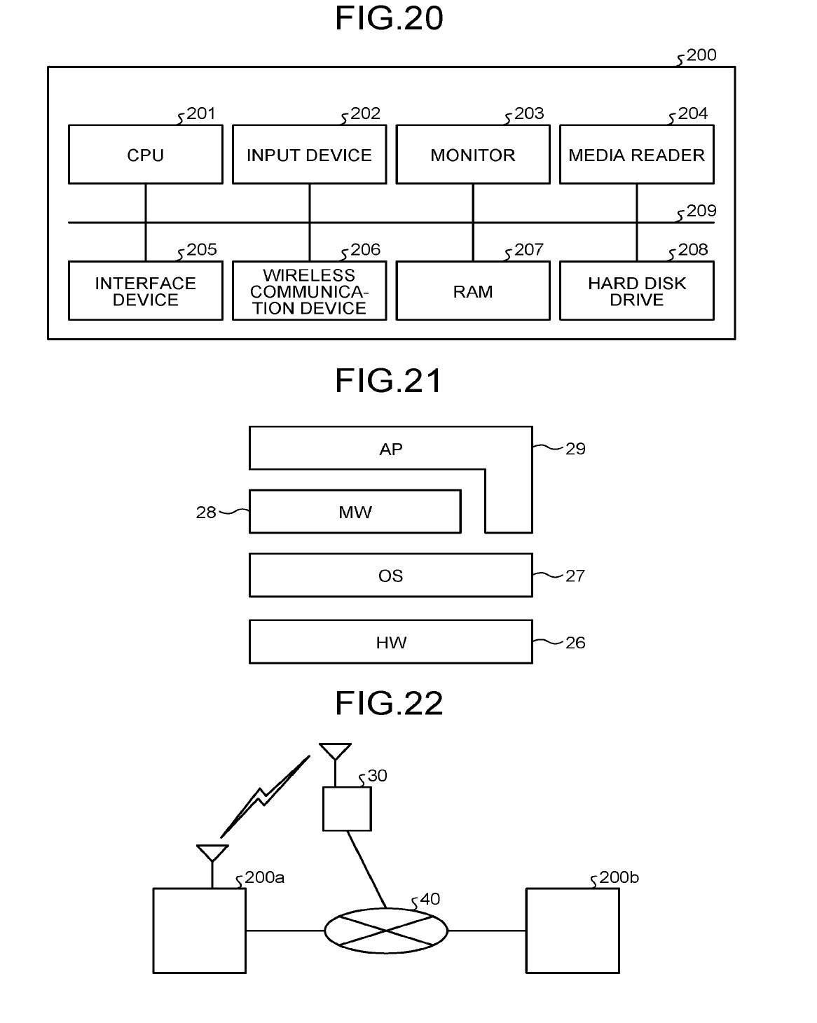

FIG. 20 is a diagram illustrating the hardware configuration of the information processing apparatus according to the first embodiment. As illustrated in FIG. 20, a computer 200 includes a CPU 201 that executes various types of processing, an input device 202 that receives an input of data from a user, and a monitor 203. The computer 200 also includes a media reader 204 that reads computer programs or the like from storage media, an interface device 205 for coupling the computer to other devices, and a wireless communication device 206 for coupling the computer to other devices through wireless connection. The computer 200 also includes a random access memory (RAM) 207 that temporarily stores various types of information, and a hard disk drive 208. All of the devices 201 to 208 are coupled to a bus 209.

The hard disk drive 208 stores therein computer programs having the same functions as the processors in the sampling unit 111, the first file reader 112, the dictionary-generating unit 113, the second file reader 114, the determination unit 115, the word-encoding unit 116, the character-encoding unit 117, and the file writer 118. The hard disk drive 208 also stores various types of data for implementing the computer programs.

The CPU 201 reads the computer programs stored in the hard disk drive 208, loads them onto the RAM 207, and executes the computer programs, thereby executing various types of processing. These computer programs can enable the computer 200 to function as the sampling unit 111, the first file reader 112, the dictionary-generating unit 113, and the second file reader 114 as illustrated in FIG. 6, for example. The computer programs can also enable the computer 200 to function as the determination unit 115, the word-encoding unit 116, the character-encoding unit 117, and the file writer 118.

The computer programs are not necessarily stored in the hard disk drive 208. For example, the computer 200 may read the computer programs stored in storage media that can be read by the computer 200, thereby executing the computer programs. Examples of the storage media that can be read by the computer 200 include portable recording media such as a compact disc read only memory (CD-ROM), a digital versatile disc (DVD), and a universal serial bus (USB), semiconductor memories such as a flash memory, and a hard disk drive. The computer programs may also be stored in a device coupled to a public network, the Internet, or the local area network (LAN), for example, from which the computer 200 may read the computer programs and execute them.

FIG. 21 is a diagram illustrating a configuration example of computer programs running on a computer. In the computer 200, an operating system (OS) 27 for controlling the pieces of hardware 26 as illustrated in FIG. 20 (the components 201 to 209) operates. The CPU 201 operates in accordance with the procedure of the OS 27, thereby controlling and administering the pieces of hardware 26. As a result, the processing in accordance with an application program 29 and middleware 28 is executed on the pieces of hardware 26. In addition, in the computer 200, the middleware 28 or the application program 29 is loaded on the RAM 207 and executed by the CPU 201.

If a compression function is called by the CPU 201, a process based on at least part of the middleware 28 or the application program 29 is executed, thereby (controlling the pieces of hardware 26 in accordance with the OS 27 and) implementing the functions of the compression unit 110. The compression functions may be included in the application program 29 itself or may be a portion of the middleware 28, which is called and executed in accordance with the application program 29.

The compressed file acquired by the compression function of the application program 29 (or the middleware 28) can also be partially expanded. Expanding a portion at a midpoint of the compressed file prevents the expansion process of the compressed data until the expanded portion, thereby reducing the load on the CPU 201. The compressed data to be expanded is partially loaded on the RAM 207, thereby reducing the working area.

FIG. 22 is a diagram illustrating a configuration example of devices in a system according to an embodiment. The system in FIG. 22 includes a computer 200a, a computer 200b, a base station 30, and a network 40. The computer 200a is coupled to the network 40 coupled to the computer 200b through at least one of wireless or wired connection.

An embodiment of the present invention has the advantageous effect of improving code lengths that are allocated to words during a compression process.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A non-transitory computer-readable recording medium having stored therein an encoding program that causes a computer to execute a process comprising:
first encoding each of first words in a target file utilizing a first code allocation rule, each of the first words having an appearance frequency larger than an appearance frequency of a word positioned at a given ordinal rank in word frequency information, the word frequency information being information of word frequencies in a plurality of files that the target file is included, the first code allocation rule being generated from the word frequency information, and
second encoding at least a second word in the target file into a code with a first code length utilizing a second code allocation rule, the second word having appearance frequency smaller than the appearance frequency of the word positioned at the given ordinal rank in the word frequency information, the second code allocation rule being different from the first code allocation rule.

2. The non-transitory computer-readable recording medium according to claim 1, wherein the first code length is equal to or larger than a maximum coding length of the words to be encoded in accordance with the first code allocation rule.

3. The non-transitory computer-readable recording medium according to claim 1, wherein the second encoding encodes each word having an appearance frequency larger than an appearance frequency of the word positioned at a second given ordinal rank out of the words having appearance frequencies smaller than the appearance frequency of the word positioned at the given ordinal rank by using the first code length, and encodes each word having an appearance frequency smaller than the appearance frequency of the word positioned at the second given ordinal rank by using a second code length different from the first code length

4. An encoding method comprising:
first encoding each of first words in a target file utilizing a first code allocation rule, each of the first words having an appearance frequency in larger than an appearance frequency of a word positioned at a given ordinal rank in word frequency information, the word frequency information being information of word frequencies in a plurality of files that the target file is included, the first code allocation rule, and
second encoding at least a second word in the target file into a code with a first code length utilizing a second code allocation rule, the second word having appearance frequency smaller than the appearance frequency of the word positioned at the given ordinal rank in the word frequency information, the second code allocation rule being different from the first code allocation rule.

5. An encoding device comprising an enencoding unit, wherein
an encoding unit encodes first encoding each of first words in a target file utilizing a first code allocation rule, each of the first words having an appearance frequency larger than an appearance frequency of a word positioned at a given ordinal rank in word frequency information, the word frequency information being information of word frequencies in a plurality of files that the target file is included, the first code allocation rule being generated from the word frequency information, and
the encoding unit encodes at least a second word in the target file into a code with a first code length utilizing a second code allocation rule, the second word having appearance frequency smaller than the appearance frequency of the word positioned at the given ordinal rank in the word frequency information, the second code allocation rule being different from the first code allocation rule.
